(19) United States
(12) Patent Application Publication
(10) Pub. No.: US 2023/0352376 A1
(43) Pub. Date: Nov. 2, 2023

(54) SEMICONDUCTOR DEVICE

(71) Applicant: ROHM CO., LTD., Kyoto-shi, Kyoto (JP)

(72) Inventor: Takumi KANDA, Kyoto-shi, Kyoto (JP)

(21) Appl. No.: 18/004,860

(22) PCT Filed: Jun. 21, 2021
(86) PCT No.: PCT/JP2021/023325

§ 371 Date: Jan. 9, 2023

(30) Foreign Application Priority Data
Jul. 20, 2020 (JP) 2020-123546

(51) Int. Cl. H01L 23/495; H01L 23/00

(52) U.S. Cl. CPC H01L 23/49562; H01L 23/49524; H01L 23/49551; H01L 24/37; H01L 24/40; H01L 24/32; H01L 24/73; H01L 24/05; H01L 24/48; H01L 24/29; H01L 2924/13091; H01L 2924/351; H01L 2224/37147; H01L 2224/32245; H01L 2224/48247; H01L 2224/04026; H01L 2224/04034; H01L 2224/05155; H01L 2224/05164; H01L 2224/05644; H01L 2224/29116; H01L 2224/37011; H01L 2224/40245; H01L 2224/73263

(57) ABSTRACT

A semiconductor device includes a first die pad having a first obverse face oriented in a thickness direction, a semiconductor element having an electrode located on a side to which the first obverse face is oriented in the thickness direction, the semiconductor element being connected to the first obverse face, a conductive material electrically connected to the electrode, and a first bonding layer electrically connecting the conductive material and the electrode. The conductive material includes a main portion, a first connecting portion electrically connected to the electrode via the first bonding layer, a first joint portion connecting the main portion and the first connecting portion, and a distal end portion spaced apart from the first joint portion, and connected to the first connecting portion. As viewed along an in-plane direction of the first obverse face, the distal end portion is inclined so as to be farther from the electrode, in a direction away from the first connecting portion. As viewed along the thickness direction, the electrode includes an expanded region, protruding from the conductive material to an opposite side of the first connecting portion in the in-plane direction, with respect to the distal end portion.

### TECHNICAL FIELD

The present disclosure relates to a semiconductor device provided with a semiconductor element.

### BACKGROUND ART

Semiconductor devices provided with a semiconductor element such as a MOSFET have thus far been widely known. Such a semiconductor device is, for example, mounted on a power conversion circuit (e.g., inverter), and converts a current according to a predetermined electric signal. Patent document 1 discloses an example of the semiconductor device that includes a MOSFET. This semiconductor device includes a drain terminal to which a source voltage is applied, a gate terminal for inputting the electric signal, and a source terminal to which the converted current flows. The MOSFET includes a drain electrode electrically connected to the drain terminal, a gate electrode electrically connected to the gate terminal, and a source electrode electrically connected to the source terminal. The drain electrode of the MOSFET is electrically connected to a die pad (connected to the drain terminal), via solder (first conductive bonding material). The source electrode of the MOSFET is electrically connected to a conductive member (metal clip), via solder (second conductive bonding material). The source terminal is also connected to the conductive member. The mentioned configuration enables the semiconductor device to withstand a large current.

In the semiconductor device of Patent Document 1, thermal stress is prone to concentrate at the interface between the source electrode and the second conductive bonding material, during the use of the device. This is because the heat generated in the MOSFET is conducted to the second conductive bonding material, through the source electrode. Here, the heat generated in the MOSFET is also conducted to the first conductive bonding material, through the drain electrode. However, the source electrode is smaller in size than the drain electrode, and therefore the thermal stress concentrates more prominently, at the interface between the source electrode and the second conductive bonding material. The concentration of the thermal stress is prone to provoke a crack in both of the source electrode and the second conductive bonding material. Therefore, it is desirable to mitigate the concentration of the thermal stress, to thereby reduce the thermal stress imposed on the MOSFET.

### PRIOR ART DOCUMENT

### Patent Document

Patent Document 1: JP-A-2016-192450

### SUMMARY OF THE INVENTION

### Problems to be Solved by the Invention

The present disclosure has been accomplished in view of the foregoing situation, and provides a semiconductor device that withstands a larger current, and yet mitigates the thermal stress imposed on the semiconductor element.

### Means to Solve the Problem

In an aspect, the present disclosure provides a semiconductor device including a first die pad having a first obverse face oriented in a thickness direction; a semiconductor element having an electrode located on a side to which the first obverse face is oriented in the thickness direction, the semiconductor element being connected to the first obverse face; a conductive member electrically connected to the electrode; and a first bonding layer electrically connecting the conductive member and the electrode. The conductive member includes a main portion, a first connecting portion electrically connected to the electrode via the first bonding layer, a first joint portion connecting the main portion and the first connecting portion, and a distal end portion spaced apart from the first joint portion, and connected to the first connecting portion. As viewed along an in-plane direction of the first obverse face, the distal end portion is inclined so as to be farther from the electrode, in a direction away from the first connecting portion. As viewed along the thickness direction, the electrode includes an expanded region, protruding from the conductive member to an opposite side of the first connecting portion in the in-plane direction, with respect to the distal end portion.

### Advantages of the Invention

With the mentioned configuration, the semiconductor device can withstand a larger current, and yet mitigate the thermal stress imposed on the semiconductor element.

Other features and advantages of the present disclosure will become more apparent, through detailed description given below with reference to the accompanying drawings.

### BRIEF DESCRIPTION OF DRAWINGS

FIG. 1 is a perspective view showing a semiconductor device according to a first embodiment of the present disclosure.

FIG. 2 is a plan view of the semiconductor device shown in FIG. 1.

FIG. 3 is a plan view corresponding to FIG. 2, seen through a sealing resin.

FIG. 4 is a bottom view of the semiconductor device shown in FIG. 1.

FIG. 5 is a front view of the semiconductor device shown in FIG. 1.

FIG. 6 is a right side view of the semiconductor device shown in FIG. 1.

FIG. 7 is a cross-sectional view taken along a line VII-VII in FIG. 3.

FIG. 8 is a cross-sectional view taken along a line VIII-VIII in FIG. 3.

FIG. 9 is a cross-sectional view taken along a line IX-IX in FIG. 3.

FIG. 10 is a cross-sectional view taken along a line X-X in FIG. 3.

FIG. 11 is a cross-sectional view taken along a line XI-XI in FIG. 3.

FIG. 12 is a plan view showing a first conductive member in the semiconductor device shown in FIG. 1.

FIG. 13 is a plan view showing a second conductive member in the semiconductor device shown in FIG. 1.

FIG. 14 is a partially enlarged view from FIG. 3.

FIG. 15 is a partially enlarged view from FIG. 7.

FIG. 16 is a partially enlarged view from FIG. 7.

FIG. 17 is a partially enlarged view from FIG. 3.

FIG. 18 is a partially enlarged view from FIG. 8.

FIG. 19 is a plan view showing a semiconductor device according to a second embodiment of the present disclosure, seen through the sealing resin.

FIG. 20 is a partially enlarged view from FIG. 19.

FIG. 21 is a cross-sectional view taken along a line XXI-XXI in FIG. 20.

### MODE FOR CARRYING OUT THE INVENTION

Hereafter, embodiments of the present disclosure will be described, with reference to the accompanying drawings.

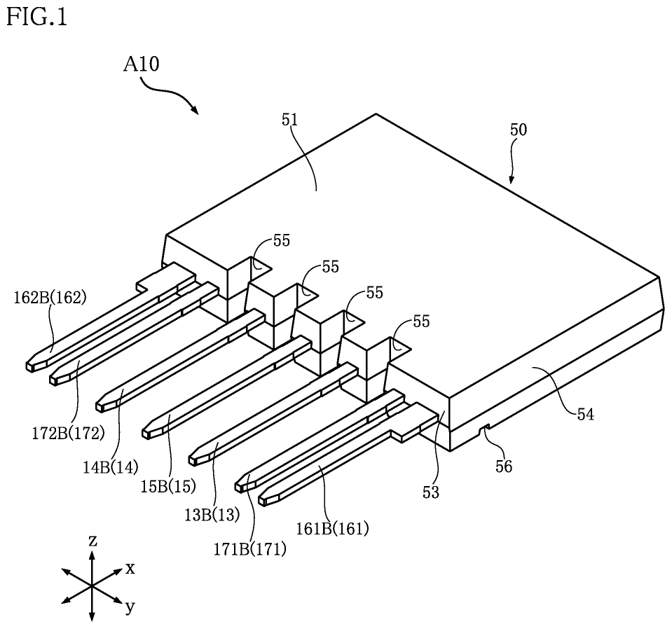

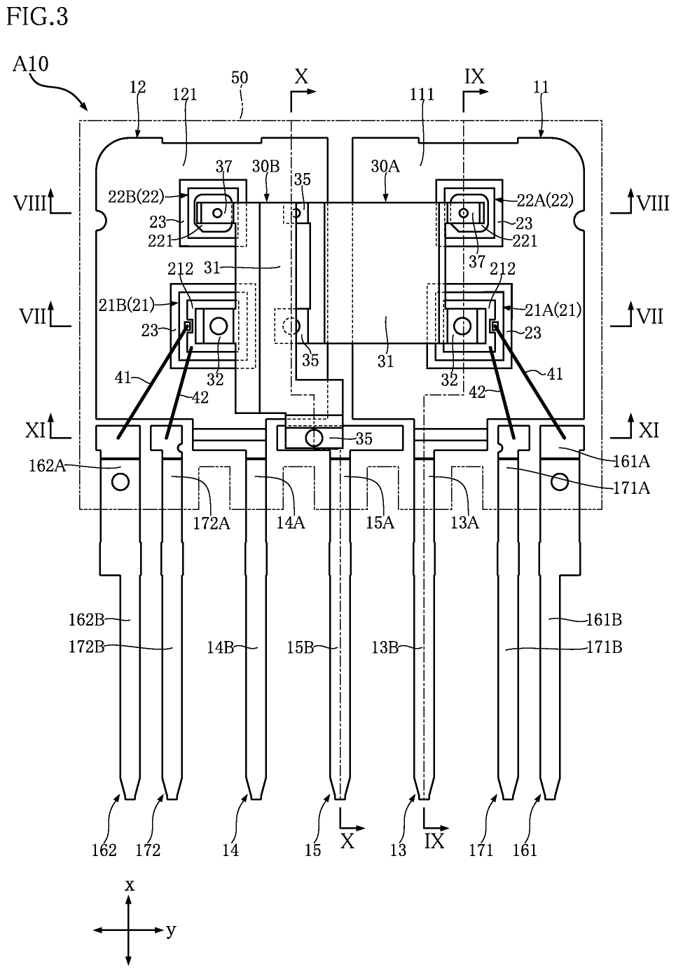

Referring to FIG. 1 to FIG. 18, a semiconductor device A10 according to a first embodiment of the present disclosure will be described. The semiconductor device A10 includes a first die pad 11, a second die pad 12, a first input terminal 13, an output terminal 14, a second input terminal 15, a pair of semiconductor elements 21, a die bonding layer 23, a first bonding layer 24, a second bonding layer 25, a first conductive member 30A, a second conductive member 30B, and a sealing resin 50. The semiconductor device A10 also includes a first gate terminal 161, a second gate terminal 162, a first detection terminal 171, a second detection terminal 172, a pair of protection elements 22, a third bonding layer 26, a pair of gate wires 41, and a pair of detection wires 42. In FIG. 3, the sealing resin 50 is seen through for the sake of clarity, and the sealing resin 50 is indicated by imaginary lines (dash-dot-dot lines). A line IX-IX and a line X-X are each indicated by dash-dot lines.

In the following description, the thickness direction of, for example, the first die pad 11 (or second die pad 12) will be defined as “thickness direction z”, for the sake of convenience. One direction orthogonal to the thickness direction z will be defined as “first direction x”. A direction orthogonal to both of the thickness direction z and the first direction x will be defined as “second direction y”. An “in-plane direction” of a first obverse face 111 of the first die pad 11 refers to a direction parallel to the first obverse face, corresponding to either of the first direction x and the second direction y as the case may be, in the present disclosure. For example, the “in-plane direction” with respect to a constituent element may refer to the first direction x, while the “in-plane direction” with respect to another constituent element may refer to the second direction y.

The semiconductor device A10 converts a DC source voltage applied to the first input terminal 13 and the second input terminal 15 to AC, with the pair of semiconductor elements 21. The converted AC is inputted to an object of power supply, such as a motor, from the output terminal 14. The semiconductor device A10 can be used in a power conversion circuit, for example an inverter.

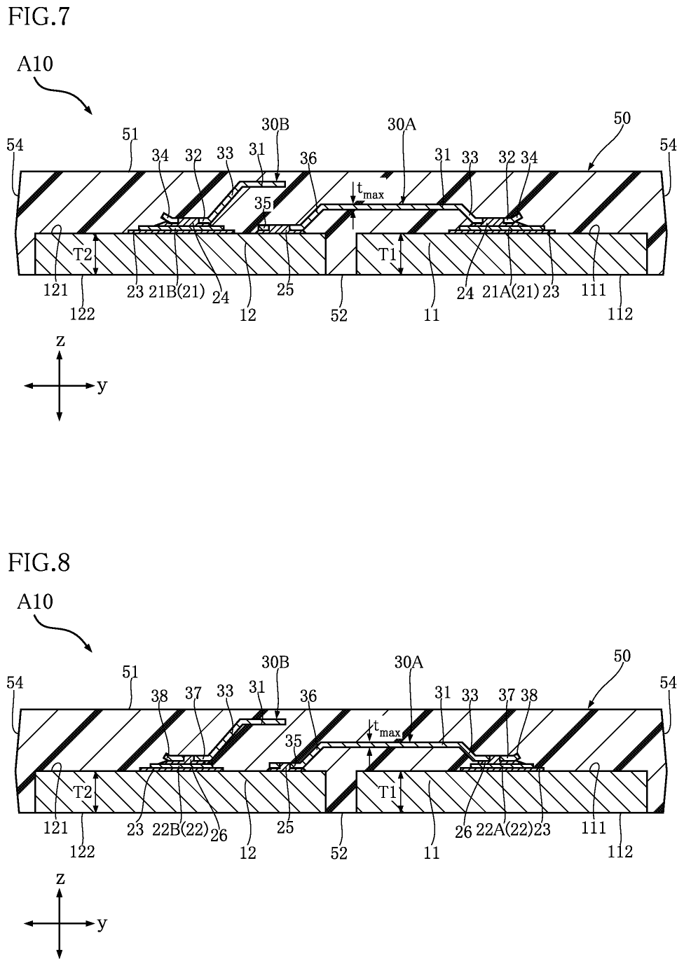

The first die pad 11 is, as shown in FIG. 3, FIG. 7, and FIG. 8, a conductive member on which one of the pair of semiconductor elements 21 (first switching element 21A) and one of the pair of protection elements 22 (first diode 22A) are mounted. The first die pad 11 is included in the same lead frame that also includes the second die pad 12, the first input terminal 13, the output terminal 14, the second input terminal 15, the first gate terminal 161, the second gate terminal 162, the first detection terminal 171, and the second detection terminal 172. The lead frame is formed of copper (Cu), or a copper-based alloy. Accordingly, the composition of each of the first die pad 11, the second die pad 12, the first input terminal 13, the output terminal 14, the second input terminal 15, the first gate terminal 161, the second gate terminal 162, the first detection terminal 171, and the second detection terminal 172 contains copper (i.e., the cited constituent elements each contain copper). The first die pad 11 includes the first obverse face 111 and a first reverse face 112. The first obverse face 111 is oriented in the thickness direction z. The first switching element 21A and the first diode 22A are mounted on the first obverse face 111. Here, the expression “An object A is mounted (arranged, provided, and the like) on another object B” in the present disclosure implies the situation where the object A and the object B are in direct contact with each other, and where at least one other object is interposed between the object A and the object B. The first reverse face 112 is oriented to the opposite side of the first obverse face 111, in the thickness direction z. The first reverse face 112 is, for example, plated with tin (Sn). As shown in FIG. 7 and FIG. 8, A thickness T1 of the first die pad 11 is thicker than a maximum thickness tₘₐₓ of the first conductive member 30A.

The second die pad 12 is, as shown in FIG. 3, FIG. 7, and FIG. 8, a conductive member on which the other of the pair of semiconductor elements 21 (second switching element 21B) and one of the pair of protection elements 22 (second diode 22B) are mounted. The second die pad 12 is spaced apart from the first die pad 11, in the in-plane direction (second direction y). The second die pad 12 includes a second obverse face 121 and a second reverse face 122. The second obverse face 121 is oriented in the same direction as the first obverse face 111, in the thickness direction z. The second switching element 21B and the second diode 22B are mounted on the second obverse face 121. The second reverse face 122 is oriented to the opposite side of the second reverse face 122, in the thickness direction z. The second reverse face 122 is, for example, plated with tin. As shown in FIG. 7 and FIG. 8, A thickness T2 of the second die pad 12 is thicker than a maximum thickness tₘₐₓ of the first conductive member 30A.

The pair of semiconductor elements 21 include the first switching element 21A and the second switching element 21B, as shown in FIG. 3 and FIG. 7. The first switching element 21A is bonded to the first obverse face 111 of the first die pad 11. The second switching element 21B is bonded to the second obverse face 121 of the second die pad 12. The pair of semiconductor elements 21 are, for example, metal-oxide-semiconductor field-effect transistors (MOSFET). In the description of the semiconductor device A10, it will be assumed that the pair of semiconductor elements 21 are each a n-channel type MOSFET of a vertical structure. The semiconductor elements 21 each include a chemical compound semiconductor substrate. The composition of the chemical compound semiconductor substrate contains silicon carbide (SiC). Alternatively, the composition of the chemical compound semiconductor substrate may contain gallium nitride (GaN). As shown in FIG. 15, the semiconductor elements 21 each include a first electrode 211, a second electrode 212, and a third electrode 213.

As shown in FIG. 15, the first electrode 211 is opposed to one of the first obverse face 111 of the first die pad 11, and the second obverse face 121 of the second die pad 12 (across the die bonding layer 23). To the first electrode 211, a voltage corresponding to the current to be converted is applied. The first electrode 211 corresponds to the drain electrode.

As shown in FIG. 15, the second electrode 212 is located on the opposite side of the first electrode 211, in the thickness direction z. In other words, the second electrode 212 is oriented in the same direction as the first obverse face 111 of the first die pad 11. To the second electrode 212, a current corresponding to the power converted by one of the pair of semiconductor elements 21 is supplied. The second electrode 212 corresponds to the source electrode. The second electrode 212 includes a plurality of metal-plated layers. The second electrode 212 includes a nickel (Ni)-plated layer, and a gold (Au)-plated layer stacked on the nickel-plated layer. Alternatively, the second electrode 212 may include the nickel-plated layer, a palladium (Pd)-plated layer stacked on the nickel-plated layer, and the gold-plated layer stacked on the palladium-plated layer.

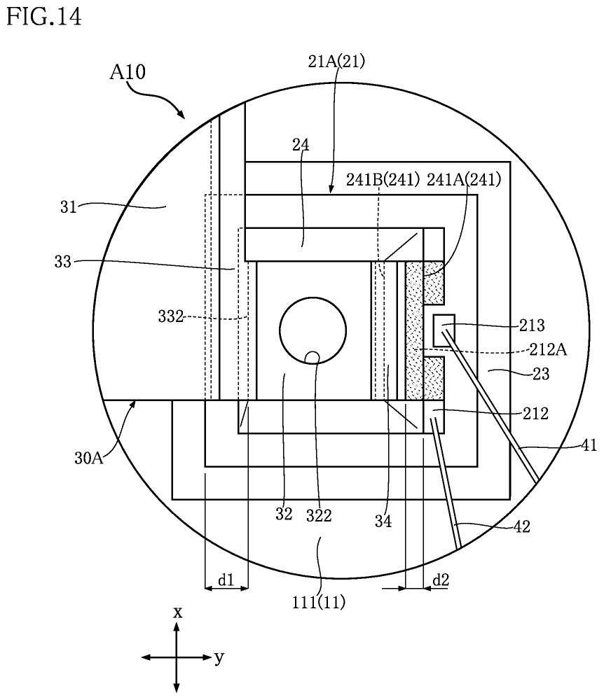

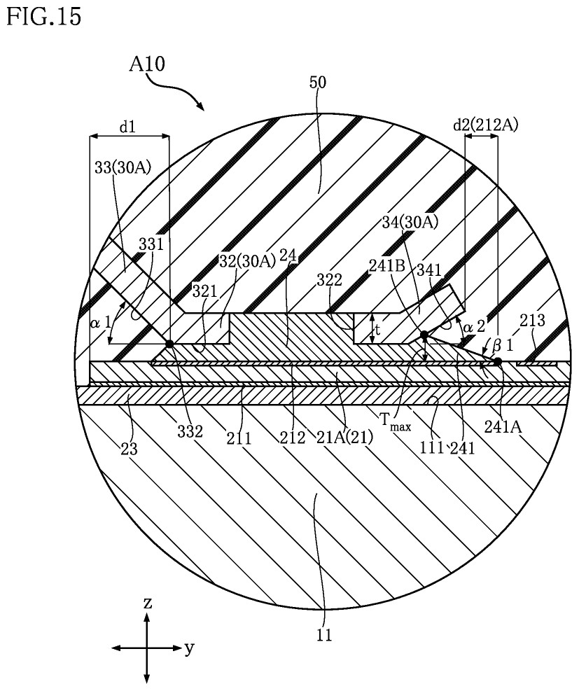

As shown in FIG. 14 and FIG. 15, the third electrode 213 is located on the same side as the second electrode 212, in the thickness direction z, and spaced apart from the second electrode 212. To the third electrode 213, a gate voltage for driving one of the pair of semiconductor elements 21 is applied. The third electrode 213 corresponds to the gate electrode. The semiconductor elements 21 each convert the current corresponding to the voltage applied to the first electrode 211, according to the gate voltage. The third electrode 213 is smaller in area than the second electrode 212, as viewed along the thickness direction z.

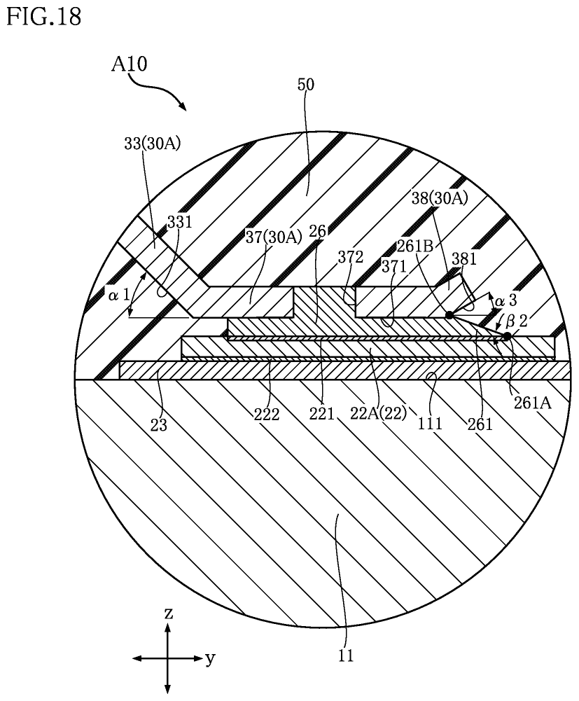

The pair of protection elements 22 include a first diode 22A and a second diode 22B, as shown in FIG. 3 and FIG. 8. The first diode 22A is bonded to the first obverse face 111 of the first die pad 11. The second diode 22B is bonded to the second obverse face 121 of the second die pad 12. Each of the protection elements 22 is, for example, a Schottky barrier diode. The first diode 22A is connected in parallel to the first switching element 21A. The second diode 22B is connected in parallel to the second switching element 21B. Each of the protection elements 22 is what is known as a freewheeling diode. Accordingly, when a reverse bias is applied to the semiconductor element 21, the current flows, not to the semiconductor element 21, but to the protection element 22 connected thereto in parallel. As shown in FIG. 18, the protection elements 22 each include an upper electrode 221 and a lower electrode 222.

As shown in FIG. 18, the upper electrode 221 is located on the side to which the first obverse face 111 of the first die pad 11 is oriented, in the thickness direction z. In each of the protection elements 22, the upper electrode 221 is electrically connected to the second electrode 212 of the semiconductor element 21, connected in parallel to the corresponding protection element 22. The upper electrode 221 corresponds to the anode electrode.

As shown in FIG. 18, the lower electrode 222 is located on the opposite side of the upper electrode 221, in the thickness direction z. In each of the protection elements 22, the lower electrode 222 is electrically connected to the first electrode 211 of the semiconductor element 21, connected in parallel to the corresponding protection element 22. The lower electrode 222 corresponds to the cathode electrode.

The die bonding layer 23 includes, as shown in FIG. 3, FIG. 15, and FIG. 18, a portion located between the first obverse face 111 of the first die pad 11 and the second obverse face 121 of the second die pad 12, and the first electrode 211 of the pair of semiconductor elements 21 and the lower electrode 222 of the pair of protection elements 22. The die bonding layer 23 is formed of an electrically conductive material. The die bonding layer 23 is, for example, formed of lead-free solder. Alternatively, the die bonding layer 23 may be formed of lead solder. The die bonding layer 23 electrically connects the first electrode 211 of the first switching element 21A and the lower electrode 222 of the first diode 22A, to the first obverse face 111. Accordingly, the first electrode 211 of the first switching element 21A, and the lower electrode 222 of the first diode 22A are electrically connected to the first die pad 11. The die bonding layer 23 electrically connects the first electrode 211 of the second switching element 21B and the lower electrode 222 of the second diode 22B, to the second obverse face 121. Accordingly, the first electrode 211 of the second switching element 21B, and the lower electrode 222 of the second diode 22B are electrically connected to the second die pad 12.

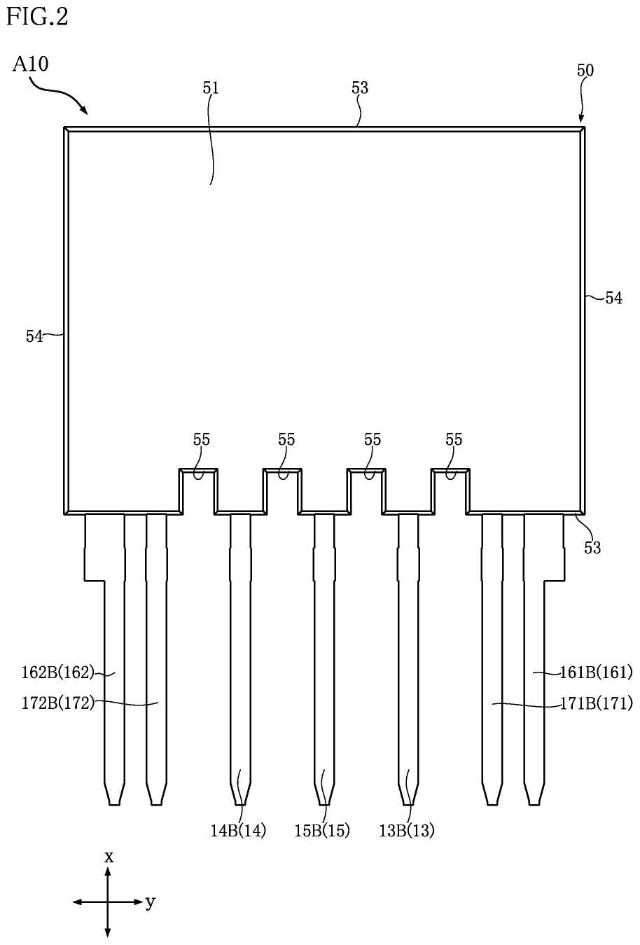

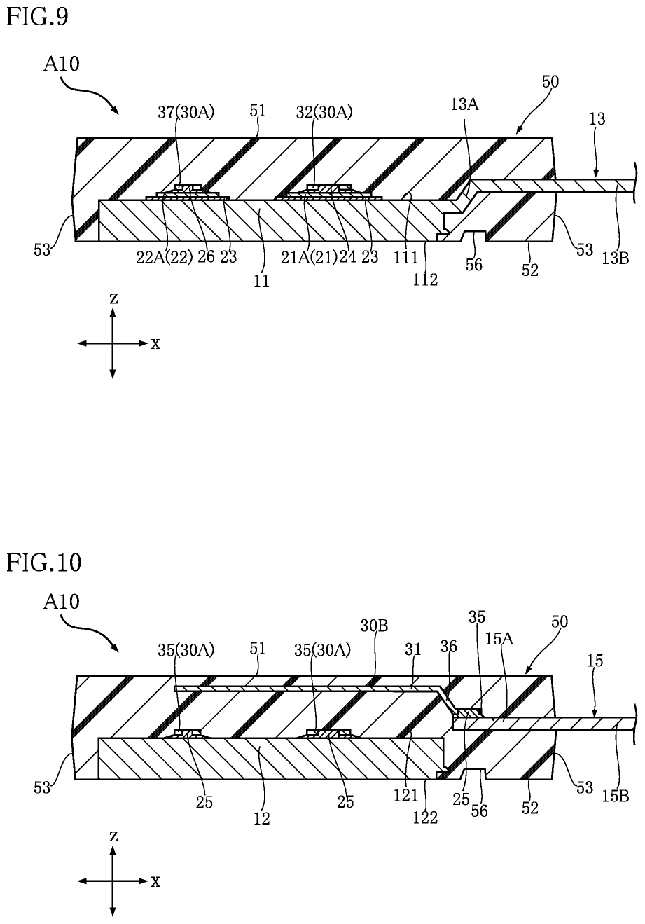

The first input terminal 13 includes a portion extending along the first direction x, and is connected to the first die pad 11, as shown in FIG. 3. Accordingly, the first input terminal 13 is electrically connected to the first die pad 11. The first input terminal 13 is a P-terminal (positive electrode), to which a DC source voltage, the object of power conversion, is applied. The first input terminal 13 includes a covered portion 13A and an exposed portion 13B. As shown in FIG. 9, the covered portion 13A is connected to the first die pad 11, and covered with the sealing resin 50. The covered portion 13A has a bent shape, as viewed along the second direction y. As shown in FIG. 2 to FIG. 5, the exposed portion 13B is connected to the covered portion 13A, and exposed from the sealing resin 50. The exposed portion 13B extends away from the first die pad 11, in the first direction x. The surface of the exposed portion 13B is, for example, tin-plated.

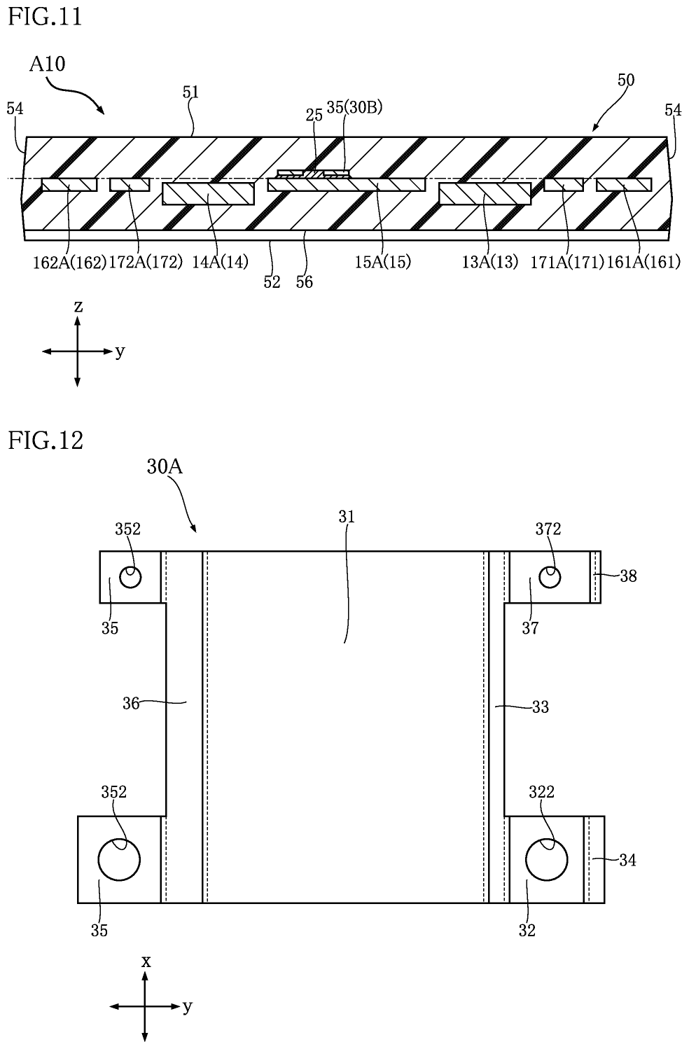

The output terminal 14 includes a portion extending along the first direction x, and is connected to the second die pad 12, as shown in FIG. 3. Accordingly, the output terminal 14 is electrically connected to the second die pad 12. The AC converted by the semiconductor element 21 is outputted from the output terminal 14. The output terminal 14 includes a covered portion 14A and an exposed portion 14B. The covered portion 14A is connected to the second die pad 12, and covered with the sealing resin 50 (see FIG. 11). The covered portion 14A has a bent shape, as viewed along the second direction y, like the covered portion 13A of the first input terminal 13. As shown in FIG. 2 to FIG. 5, the exposed portion 14B is connected to the covered portion 14A, and exposed from the sealing resin 50. The exposed portion 14B extends away from the second die pad 12, in the first direction x. The surface of the exposed portion 14B is, for example, tin-plated.

The second input terminal 15 is, as shown in FIG. 3, spaced apart from both of the first die pad 11 and the second die pad 12 in the first direction x, and located between the first input terminal 13 and the output terminal 14, in the second direction y. The second input terminal 15 extends along the first direction x. The second input terminal 15 is electrically connected to the second electrode 212 of the second switching element 21B, and the upper electrode 221 of the second diode 22B. The second input terminal 15 is an N-terminal (negative electrode), to which a source voltage (corresponding to DC to be converted) is applied. The second input terminal 15 includes a covered portion 15A and an exposed portion 15B. As shown in FIG. 10, the covered portion 15A is covered with the sealing resin 50. As shown in FIG. 2 to FIG. 5, the exposed portion 15B is connected to the covered portion 15A, and exposed from the sealing resin 50. The exposed portion 15B extends away from both of the first die pad 11 and the second die pad 12, in the first direction x. The surface of the exposed portion 15B is, for example, tin-plated.

The first gate terminal 161 is, as shown in FIG. 3, spaced apart from the first die pad 11 in the first direction x, and located at an end portion in the second direction y. The second gate terminal 162 is, as shown in FIG. 3, spaced apart from the second die pad 12 in the first direction x, and located at the other end portion in the second direction y. The first gate terminal 161 is electrically connected to the third electrode 213 of the first switching element 21A. To the first gate terminal 161, a gate voltage for driving the first switching element 21A is applied. The second gate terminal 162 is electrically connected to the third electrode 213 of the second switching element 21B. To the second gate terminal 162, a gate voltage for driving the second switching element 21B is applied.

As shown in FIG. 3, the first gate terminal 161 includes a covered portion 161A and an exposed portion 161B. As shown in FIG. 11, the covered portion 161A is covered with the sealing resin 50. As shown in FIG. 2 to FIG. 5, the exposed portion 161B is connected to the covered portion 161A, and exposed from the sealing resin 50. The exposed portion 161B extends away from the first die pad 11, in the first direction x. The surface of the exposed portion 161B is, for example, tin-plated.

As shown in FIG. 3, the second gate terminal 162 includes a covered portion 162A and an exposed portion 162B. As shown in FIG. 11, the covered portion 162A is covered with the sealing resin 50. As shown in FIG. 2 to FIG. 5, the exposed portion 162B is connected to the covered portion 162A, and exposed from the sealing resin 50. The exposed portion 162B extends away from the second die pad 12, in the first direction x. The surface of the exposed portion 162B is, for example, tin-plated.

The first detection terminal 171 is, as shown in FIG. 3, spaced apart from the first die pad 11 in the first direction x, and located between the first input terminal 13 and the first gate terminal 161, in the second direction y. The second detection terminal 172 is, as shown in FIG. 3, spaced apart from the second die pad 12 in the first direction x, and located between the output terminal 14 and the second gate terminal 162, in the second direction y. The first detection terminal 171 is electrically connected to the second electrode 212 of the first switching element 21A. To the first detection terminal 171, a voltage corresponding to the current flowing to the second electrode 212 of the first switching element 21A is applied. The second detection terminal 172 is electrically connected to the second electrode 212 of the second switching element 21B. To the second detection terminal 172, a voltage corresponding to the current flowing to the second electrode 212 of the second switching element 21B is applied.

As shown in FIG. 3, the first detection terminal 171 includes a covered portion 171A and an exposed portion 171B. As shown in FIG. 11, the covered portion 171A is covered with the sealing resin 50. As shown in FIG. 2 to FIG. 5, the exposed portion 171B is connected to the covered portion 171A, and exposed from the sealing resin 50. The exposed portion 171B extends away from the first die pad 11, in the first direction x. The surface of the exposed portion 171B is, for example, tin-plated.

As shown in FIG. 3, the second detection terminal 172 includes a covered portion 172A and an exposed portion 172B. As shown in FIG. 11, the covered portion 172A is covered with the sealing resin 50. As shown in FIG. 2 to FIG. 5, the exposed portion 172B is connected to the covered portion 172A, and exposed from the sealing resin 50. The exposed portion 172B extends away from the second die pad 12, in the first direction x. The surface of the exposed portion 172B is, for example, tin-plated.

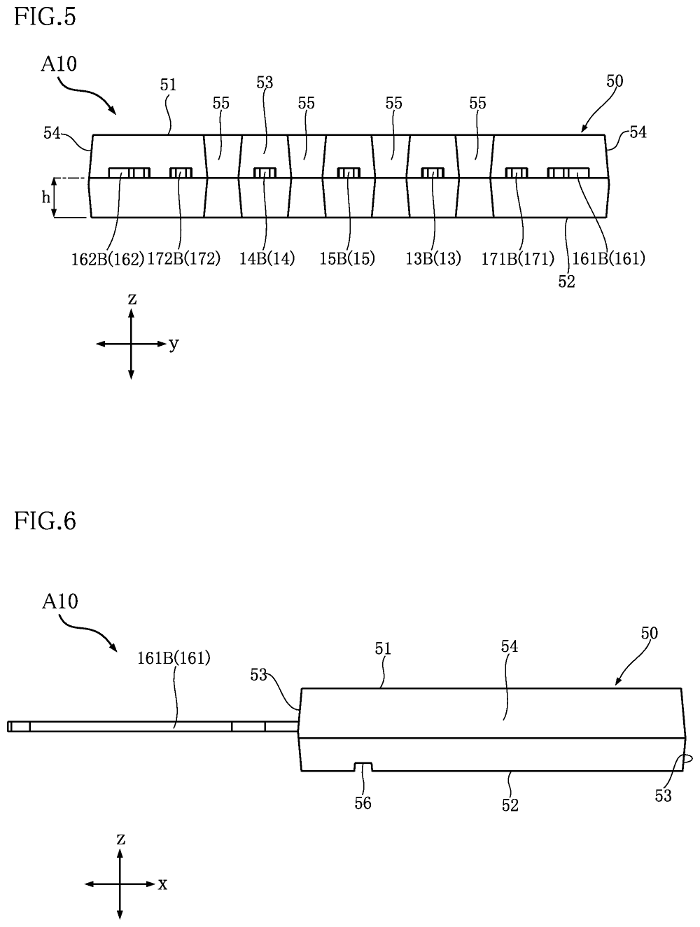

In the semiconductor device A10, as shown in FIG. 5, the exposed portion 13B of the first input terminal 13, the exposed portion 14B of the output terminal 14, and the exposed portion 15B of the second input terminal 15 have the same height h. These exposed portions also have the same thickness. Accordingly, as viewed along the second direction y, at least a part of the second input terminal 15 (exposed portion 15B) overlaps with the first input terminal 13 and the output terminal 14 (see FIG. 6).

The first conductive member 30A is, as shown in FIG. 3, electrically connected to the second electrode 212 of the first switching element 21A, the upper electrode 221 of the first diode 22A, and the second obverse face 121 of the second die pad 12. Accordingly, the second electrode 212 of the first switching element 21A and the upper electrode 221 of the first diode 22A are electrically connected to each other, and also electrically connected to the second die pad 12. The second conductive member 30B is, as shown in FIG. 3, connected to the second electrode 212 of the second switching element 21B, the upper electrode 221 of the second diode 22B, and the covered portion 15A of the second input terminal 15. Accordingly, the second electrode 212 of the second switching element 21B and the upper electrode 221 of the second diode 22B are electrically connected to each other, and also electrically connected to the second input terminal 15.

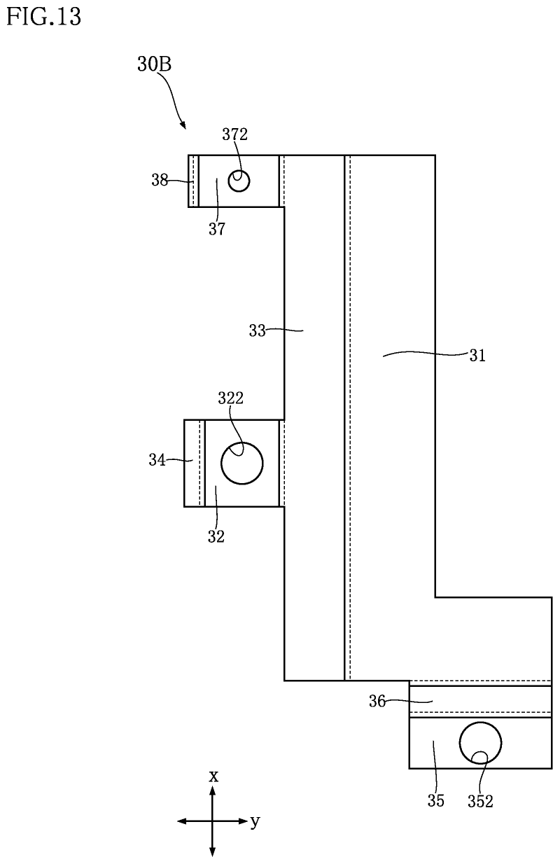

The composition of each of the first conductive member 30A and the second conductive member 30B contains copper. In the semiconductor device A10, the first conductive member 30A and the second conductive member 30B are each a metal clip. As shown in FIG. 12 and FIG. 13, the first conductive member 30A and the second conductive member 30B each include a main portion 31, a first connecting portion 32, a first joint portion 33, a distal end portion 34, a second connecting portion 35, a second joint portion 36, a third connecting portion 37, and a distal end portion 38.

As shown in FIG. 12 and FIG. 13, the main portion 31 constitutes the principal section of each of the first conductive member 30A and the second conductive member 30B. As shown in FIG. 7, FIG. 8, and FIG. 10, the main portion 31 is parallel to the first obverse face 111 of the first die pad 11, and the second obverse face 121 of the second die pad 12. The main portion 31 of the second conductive member 30B is more distant from both of the first obverse face 111 and the second obverse face 121, than the main portion 31 of the first conductive member 30A is, and strides over the second connecting portion 35 of the first conductive member 30A.

As shown in FIG. 3 and FIG. 7, the first connecting portion 32 is electrically connected to the second electrode 212 of one of the pair of semiconductor elements 21. The first connecting portion 32 of the first conductive member 30A is electrically connected to the second electrode 212 of the first switching element 21A. The first connecting portion 32 of the second conductive member 30B is electrically connected to the second electrode 212 of the second switching element 21B. The first connecting portion 32 is parallel to the second electrode 212 of one of the pair of semiconductor elements 21. As shown in FIG. 15, the first connecting portion 32 includes a first connecting surface 321 and a first opening 322. The first connecting surface 321 is opposed to the second electrode 212 of one of the pair of semiconductor elements 21. The first opening 322 is penetrating through the first connecting portion 32 in the thickness direction z. As shown in FIG. 14, the first opening 322 has a circular shape, as viewed along the thickness direction z. The area of the first opening 322 (opening area) is equal to or larger than 0.25 mm².

As shown in FIG. 7, FIG. 12, and FIG. 13, the first joint portion 33 is connecting between the main portion 31 and the first connecting portion 32. As shown in FIG. 7, the first joint portion 33 is inclined so as to be farther from one of the first obverse face 111 of the first die pad 11 and the second obverse face 121 of the second die pad 12, in the direction from the first connecting portion 32 toward the main portion 31, as viewed along the in-plane direction (first direction x). As shown in FIG. 15, the first joint portion 33 includes a first inclined surface 331 and a boundary 332. The first inclined surface 331 is connected to the first connecting surface 321 of the first connecting portion 32, and inclined with respect to the first connecting surface 321. In a view along the in-plane direction (first direction x), an inclination angle α1, defined by the first inclined surface 331 with respect to the first connecting surface 321, is between 30° and 60°, both ends inclusive. The boundary 332 corresponds to the borderline between the first connecting surface 321 and the first inclined surface 331. As shown in FIG. 14, as viewed along the thickness direction z, the boundary 332 is located on the inner side of the peripheral edge of one of the pair of semiconductor elements 21. A shortest distance d1 between the peripheral edge and the boundary 332 is between 0.2 mm and 0.5 mm, both ends inclusive.

As shown in FIG. 7, FIG. 12, and FIG. 13, the distal end portion 34 is spaced apart from the first joint portion 33, and connected to the first connecting portion 32. The distal end portion 34 is located on the opposite side of the first joint portion 33 in the in-plane direction (second direction y), with respect to the first connecting portion 32. As shown in FIG. 15, the distal end portion 34 is inclined so as to be farther from the second electrode 212 of one of the pair of semiconductor elements 21, in the direction away from the first connecting portion 32, as viewed along the in-plane direction (first direction x). As shown in FIG. 14, the second electrode 212 of the first switching element 21A includes an expanded region 212A, protruding from the first conductive member 30A to the opposite side of the first connecting portion 32 in the in-plane direction (second direction y), with respect to the distal end portion 34. Although not shown, the second electrode 212 of the second switching element 21B also includes the expanded region 212A, similarly protruding from the second conductive member 30B. As viewed along the thickness direction z, a smallest size d2 of the expanded region 212A (size in the second direction y, in the semiconductor device A10) is between 0.1 mm and 0.2 mm, both ends inclusive.

As shown in FIG. 15, the distal end portion 34 includes a bent surface 341. The bent surface 341 is connected to the first connecting surface 321 of the first connecting portion 32, and inclined with respect to the first connecting surface 321. As viewed along the in-plane direction (first direction x), the bent surface 341 defines an inclination angle α2, with respect to the first connecting surface 321.

As viewed along the thickness direction z, a ratio of the total area of the first connecting portion 32 and the distal end portion 34 (except the area of the first opening 322), to the area of the second electrode 212 of one of the pair of semiconductor elements 21, is between 50% and 90%, both ends inclusive.

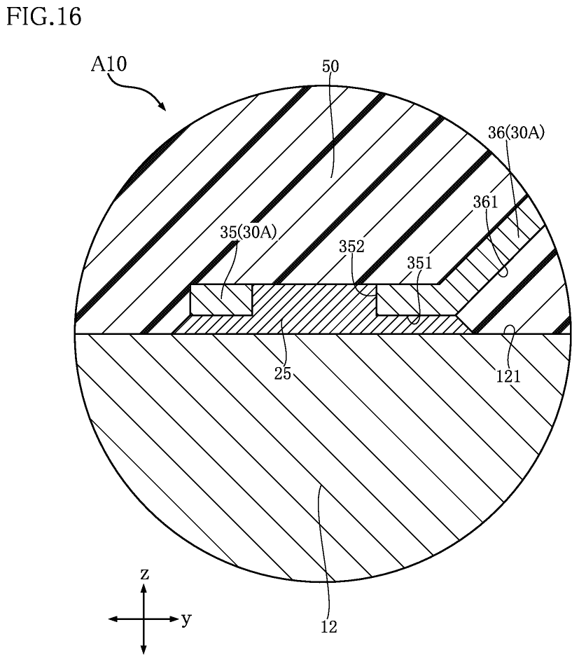

As shown in FIG. 3, FIG. 10, and FIG. 11, the second connecting portion 35 is electrically connected to one of the second obverse face 121 of the second die pad 12, and the covered portion 15A of the second input terminal 15. The second connecting portion 35 of the first conductive member 30A is electrically connected to the second obverse face 121, and parallel thereto. In the semiconductor device A10, the second connecting portion 35 of the first conductive member 30A includes two regions spaced apart from each other, in the first direction x. The second connecting portion 35 of the second conductive member 30B is electrically connected to the covered portion 15A, and parallel thereto. As show in FIG. 16, the second connecting portion 35 includes a second connecting surface 351 and a second opening 352. The second connecting surface 351 is opposed to one of the second obverse face 121 and the covered portion 15A. The second opening 352 is penetrating through the second connecting portion 35, in the thickness direction z. As shown in FIG. 12 and FIG. 13, the second opening 352 has a circular shape, as viewed along the thickness direction z. The opening area of the second opening 352 is equal to or larger than 0.25=2.

As shown in FIG. 7, FIG. 8, FIG. 10, FIG. 12, and FIG. 13, the second joint portion 36 is connecting between the main portion 31 and the second connecting portion 35. The second joint portion 36 of the first conductive member 30A is inclined so as to be farther from the second obverse face 121 of the second die pad 12, in the direction from the second connecting portion 35 toward the main portion 31, as viewed along the in-plane direction (first direction x). The second joint portion 36 of the second conductive member 30B is inclined so as to be farther from the covered portion 15A of the second input terminal 15, in the direction from the second connecting portion 35 toward the main portion 31, as viewed along the in-plane direction (second direction y). As shown in FIG. 16, the second joint portion 36 includes a second inclined surface 361. The second inclined surface 361 is connected to the second connecting surface 351 of the second connecting portion 35, and inclined with respect to the second connecting surface 351.

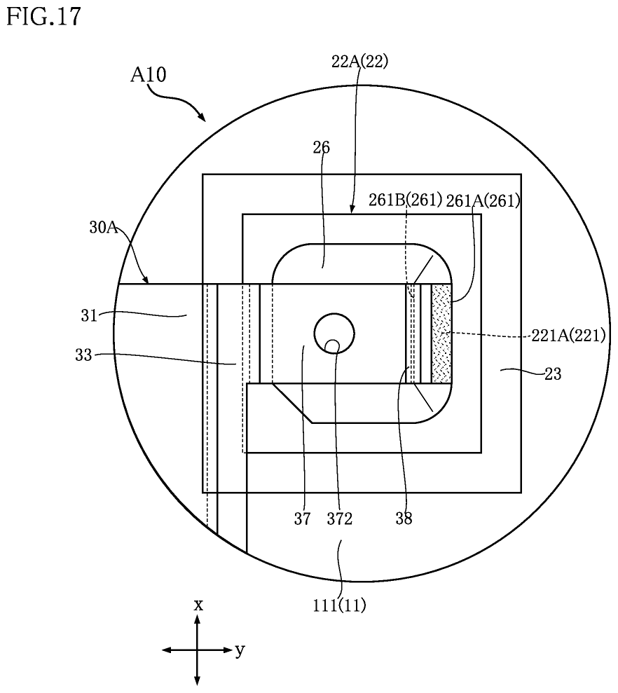

As shown in FIG. 3 and FIG. 8, the third connecting portion 37 is electrically connected to the upper electrode 221 of one of the pair of protection elements 22. The third connecting portion 37 of the first conductive member 30A is electrically connected to the upper electrode 221 of the first diode 22A. The third connecting portion 37 of the second conductive member 30B is electrically connected to the upper electrode 221 of the second diode 22B. The third connecting portion 37 is parallel to the upper electrode 221 of one of the pair of protection elements 22. As shown in FIG. 12 and FIG. 13, the third connecting portion 37 is connected to the first joint portion 33. As shown in FIG. 18, the third connecting portion 37 includes a third connecting surface 371 and a third opening 372. The third connecting surface 371 is opposed to the upper electrode 221 of one of the pair of protection elements 22. The third connecting surface 371 is connected to the first inclined surface 331 of the first joint portion 33. As viewed along the in-plane direction (first direction x), the first inclined surface 331 defines an inclination angle α1, with respect to the third connecting surface 371. The third opening 372 is penetrating through the third connecting portion 37, in the thickness direction z. As shown in FIG. 17, the third opening 372 has a circular shape, as viewed along the thickness direction z. The opening area of the second opening 372 is equal to or larger than 0.25 mm².

As shown in FIG. 7, FIG. 12, and FIG. 13, the distal end portion 38 is spaced apart from the first joint portion 33, and connected to the third connecting portion 37. The distal end portion 38 is located on the opposite side of the first joint portion 33 in the in-plane direction (second direction y), with respect to the third connecting portion 37. As shown in FIG. 18, the distal end portion 38 is inclined so as to be farther from the upper electrode 221 of one of the pair of protection elements 22, in the direction away from the third connecting portion 37, as viewed along the in-plane direction (first direction x). As shown in FIG. 17, the upper electrode 221 of the first diode 22A includes an expanded region 221A, protruding from the first conductive member 30A to the opposite side of the third connecting portion 37 in the in-plane direction (second direction y), with respect to the distal end portion 38. Although not shown, the upper electrode 221 of the second diode 22B also includes the expanded region 221A, similarly protruding from the second conductive member 30B.

As shown in FIG. 18, the distal end portion 38 includes a bent surface 381. The bent surface 381 is connected to the third connecting surface 371 of the third connecting portion 37, and inclined with respect to the third connecting surface 371. As viewed along the in-plane direction (first direction x), the bent surface 381 defines an inclination angle α3, with respect to the third connecting surface 371.

The first bonding layer 24 includes, as shown in FIG. 7 and FIG. 15, a portion located between the second electrode 212 of each of the pair of semiconductor elements 21, and the first connecting portion 32 of one of the first conductive member 30A and the second conductive member 30B. The first bonding layer 24 is electrically conductive. The first bonding layer 24 is, for example, formed of lead-free solder. Alternatively, the first bonding layer 24 may be formed of lead solder. The first bonding layer 24 is electrically connecting between each of the first conductive member 30A and the second conductive member 30B, and the second electrode 212 of one of the pair of semiconductor elements 21. Accordingly, the first connecting portion 32 of the first conductive member 30A is electrically connected to the second electrode 212 of the first switching element 21A, via the first bonding layer 24. The first connecting portion 32 of the second conductive member 30B is electrically connected to the second electrode 212 of the second switching element 21B, via the first bonding layer 24.

As shown in FIG. 15, the first bonding layer 24 is in contact with the first connecting surface 321 of the first connecting portion 32 of each of the first conductive member 30A and the second conductive member 30B. The first bonding layer 24 is also in contact with the inner circumferential surface of the first connecting portion 32, defining the first opening 322 of the first connecting portion 32. Accordingly, the first bonding layer 24 includes the portion penetrating into the first opening 322. A thickness t of the first connecting portion 32 is equal to or thicker than 0.1 mm, and equal to or thinner than twice of a maximum thickness Tₘₐₓ of the first bonding layer 24. Here, the maximum thickness Tₘₐₓ of the first bonding layer 24 does not include the portion of the first bonding layer 24 penetrating into the first opening 322. The maximum thickness Tₘₐₓ of the first bonding layer 24 is thicker than the thickness of each of the pair of semiconductor elements 21.

As shown in FIG. 15, as viewed along the in-plane direction (first direction x), the first bonding layer 24 includes a fillet 241, formed on the second electrode 212 of the first switching element 21A so as to reach the first conductive member 30A, and inclined with respect to the second electrode 212. Although not shown, the fillet 241 is also formed in the portion of the first bonding layer 24 located between the second electrode 212 of the second switching element 21B and the first connecting portion 32 of the second conductive member 30B. The following description refers to the fillet 241 formed in the portion of the first bonding layer 24 located between the second electrode 212 of the first switching element 21A and the first connecting portion 32 of the first conductive member 30A. As shown in FIG. 15, the fillet 241 includes a first edge 241A in contact with the second electrode 212 of the first switching element 21A, and a second edge 241B in contact with the first conductive member 30A. As shown in FIG. 14, as viewed along the thickness direction z, the first edge 241A is located on the outer side from the second edge 241B. In other words, as viewed along the thickness direction, the first edge 241A is located closer to the outer edge of the first switching element 21A (right edge in FIG. 14) than the second edge 241B is. In the semiconductor device A10, the second edge 241B is in contact with the bent surface 341 of the distal end portion 34. In a view along the in-plane direction (first direction x), an inclination angle (31, defined by the fillet 241 with respect to the second electrode 212 of the first switching element 21A, is narrower than the inclination angle α2 defined by the bent surface 341 with respect to the first connecting surface 321 of the first connecting portion 32.

The second bonding layer 25 includes, as shown in FIG. 8 and FIG. 16, a portion located between the second obverse face 121 of the second die pad 12, and the second connecting portion 35 of the first conductive member 30A, and is in contact with the second connecting surface 351 of the second connecting portion 35. The second bonding layer 25 is electrically conductive. The second bonding layer 25 is, for example, formed of lead-free solder. Alternatively, the second bonding layer 25 may be formed of lead solder. The second bonding layer 25 is electrically connecting between the first conductive member 30A and the second obverse face 121. Accordingly, the second connecting portion 35 of the first conductive member 30A is electrically connected to the second obverse face 121, via the second bonding layer 25. Further, the second bonding layer 25 includes, as shown in FIG. 10 and FIG. 11, a portion located between the covered portion 15A of the second input terminal 15, and the second connecting portion 35 of the second conductive member 30B, and is in contact with the second connecting portion 35. The second bonding layer 25 is electrically connecting between the second conductive member 30B and the covered portion 15A. Accordingly, the second connecting portion 35 of the second conductive member 30B is electrically connected to the covered portion 15A, via the second bonding layer 25. As shown in FIG. 16, the second bonding layer 25 is also in contact with the inner circumferential surface of the second connecting portion 35, defining the second opening 352 of the second connecting portion 35. Accordingly, the second bonding layer 25 includes the portion penetrating into the second opening 352.

The third bonding layer 26 includes, as shown in FIG. 8 and FIG. 18, a portion located between the upper electrode 221 of each of the pair of protection elements 22, and the third connecting portion 37 of one of the first conductive member 30A and the second conductive member 30B. The third bonding layer 26 is electrically conductive. The third bonding layer 26 is, for example, formed of lead-free solder. Alternatively, the third bonding layer 26 may be formed of lead solder. The third bonding layer 26 is electrically connecting between each of the first conductive member 30A and the second conductive member 30B, and the upper electrode 221 of one of the pair of protection elements 22. Accordingly, the third connecting portion 37 of the first conductive member 30A is electrically connected to the upper electrode 221 of the first diode 22A, via the third bonding layer 26. The third connecting portion 37 of the second conductive member 30B is electrically connected to the upper electrode 221 of the second diode 22B, via the third bonding layer 26.

As shown in FIG. 18, the third bonding layer 26 is in contact with the third connecting surface 371 of the third connecting portion 37 of each of the first conductive member 30A and the second conductive member 30B. The third bonding layer 26 is also in contact with the inner circumferential surface of the third connecting portion 37, defining the third opening 372 of the third connecting portion 37. Accordingly, the third bonding layer 26 includes the portion penetrating into the third opening 372.

As shown in FIG. 18, as viewed along the in-plane direction (first direction x), the third bonding layer 26 includes a fillet 261, formed on the upper electrode 221 of the first diode 22A so as to reach the first conductive member 30A, and inclined with respect to the upper electrode 221. Although not shown, the fillet 261 is also formed in the portion of the third bonding layer 26 located between the upper electrode 221 of the second diode 22B and the third connecting portion 37 of the second conductive member 30B. The following description refers to the fillet 261 formed in the portion of the third bonding layer 26 located between the upper electrode 221 of the first diode 22A and the third connecting portion 37 of the first conductive member 30A. As shown in FIG. 18, the fillet 261 includes a first edge 261A in contact with the upper electrode 221 of the first diode 22A, and a second edge 261B in contact with the first conductive member 30A. As shown in FIG. 17, as viewed along the thickness direction z, the first edge 261A is located on the outer side from the second edge 261B. In the semiconductor device A10, the second edge 261B is in contact with the bent surface 381 of the distal end portion 38. In a view along the in-plane direction (first direction x), an inclination angle β2, defined by the fillet 261 with respect to the upper electrode 221 of the first diode 22A, is narrower than the inclination angle α3 defined by the bent surface 381 with respect to the third connecting surface 371 of the third connecting portion 37.

As shown in FIG. 3, the pair of gate wires 41 include a first gate wire 41 (e.g., gate wire 41 on the right) and a second gate wire 41 (e.g., gate wire 41 on the left). The first gate wire 41 is electrically connected between the third electrode 213 (see FIG. 14) of one of the pair of semiconductor elements 21, and the covered portion 161A of the first gate terminal 161. The second gate wire 41 is electrically connected between the third electrode 213 of the other of the pair of semiconductor elements 21, and the covered portion 162A of the second gate terminal 162. Accordingly, the first gate terminal 161 is electrically connected to the third electrode 213 of the first switching element 21A, and the second gate terminal 162 is electrically connected to the third electrode 213 of the second switching element 21B. The composition of each of the gate wires 41 contains gold, without limitation thereto. For example, the composition of each of the gate wires 41 may contain copper, or aluminum (Al).

As shown in FIG. 3, the pair of detection wires 42 include a first detection wire 42 (e.g., detection wire 42 on the right) and a second detection wire 42 (e.g., detection wire 42 on the left). The first detection wire 42 is electrically connected between the second electrode 212 (see FIG. 14) of one of the pair of semiconductor elements 21, and the covered portion 171A of the first detection terminal 171. The second detection wire 42 is electrically connected between the second electrode 212 of the other of the pair of semiconductor elements 21, and the covered portion 172A of the second detection terminal 172. Accordingly, the first detection terminal 171 is electrically connected to the second electrode 212 of the first switching element 21A, and the second detection terminal 172 is electrically connected to the second electrode 212 of the second switching element 21B. The composition of each of the detection wires 42 contains gold, without limitation thereto. For example, the composition of each of the detection wires 42 may contain copper, or aluminum (Al).

The sealing resin 50 covers, as shown in FIG. 3 and FIG. 7 to FIG. 10, the semiconductor elements 21, the protection elements 22, the first conductive member 30A, and the second conductive member 30B. The sealing resin 50 also covers a part of the first die pad 11, and a part of the second die pad 12. The sealing resin 50 is electrically insulative. The sealing resin 50 is, for example, formed of a material containing a black epoxy resin. The sealing resin 50 includes a top face 51, a bottom face 52, a pair of first side faces 53, a pair of second side faces 54, a plurality of recesses 55, and a groove 56.

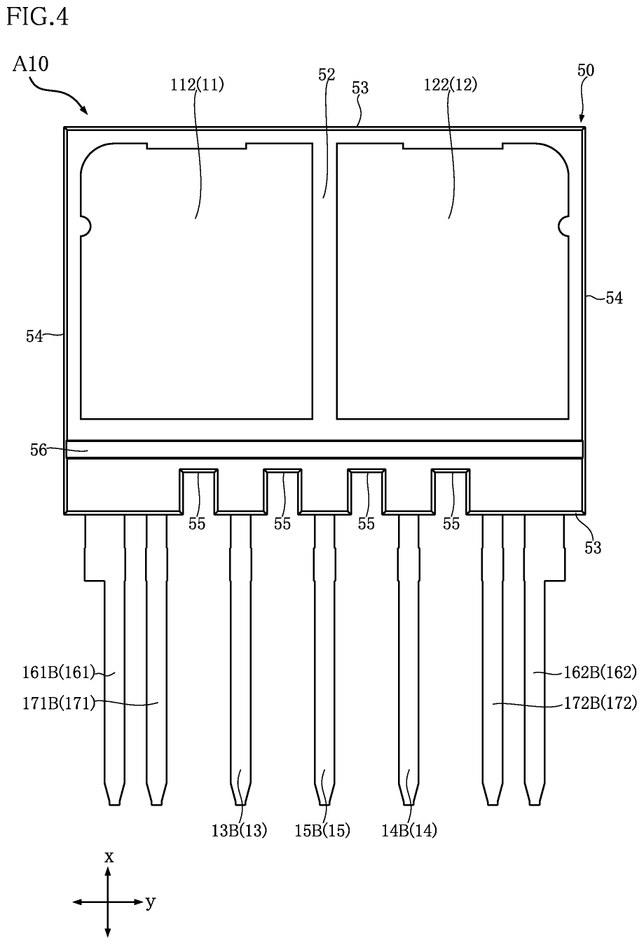

As shown in FIG. 7 to FIG. 10, the top face 51 is oriented in the same direction as the first obverse face 111 of the first die pad 11, in the thickness direction z. As shown in FIG. 7 to FIG. 10, the bottom face 52 is oriented to the opposite side of the top face 51, in the thickness direction z. As shown in FIG. 4, the first reverse face 112 of the first die pad 11, and the second reverse face 122 of the second die pad 12 are exposed to outside, from the bottom face 52.

As shown in FIG. 2, FIG. 4, and FIG. 6, the pair of first side faces 53 are spaced apart from each other in the first direction x. The first side faces 53 are each connected to the top face 51 and the bottom face 52. As shown in FIG. 5, the exposed portion 13B of the first input terminal 13, the exposed portion 14B of the output terminal 14, and the exposed portion 15B of the second input terminal 15 are exposed from one of the first side faces 53. In addition, the exposed portion 161B of the first gate terminal 161, the exposed portion 162B of the second gate terminal 162, the exposed portion 171B of the first detection terminal 171, and the exposed portion 172B of the second detection terminal 172 are exposed, from the same first side face 53.

As shown in FIG. 2, FIG. 4, and FIG. 5, the pair of second side faces 54 are spaced apart from each other in the second direction y. The second side faces 54 are each connected to the top face 51 and the bottom face 52.

As shown in FIG. 2, FIG. 4, and FIG. 5, the plurality of recesses 55 are each recessed in the first direction x from the first side face 53 (from which the plurality of terminals, including the first input terminal 13, are sticking out), and extend from the top face 51 to the bottom face 52, in the thickness direction z. Although four recesses 55 are provided in the illustrated example, the present disclosure is not limited thereto. A first recess 55 of the four (e.g., recess 55 at the right end in FIG. 2) is located between the first input terminal 13 and the first detection terminal 171, in the second direction y. A second recess 55 is located between the first input terminal 13 and the second input terminal 15, a third recess 55 is located between the output terminal 14 and the second input terminal 15, and a fourth recess 55 (recess 55 at the left end in FIG. 2) is located between the output terminal 14 and the second detection terminal 172. Arranging thus the plurality of recesses 55 enables a creepage distance between two given terminals along the sealing resin 50 (distance measured along the surface of the sealing resin 50) to be increased. For example, the creepage distance along the sealing resin 50 between two given terminals, out of the first input terminal 13, the output terminal 14, the second input terminal 15, the first detection terminal 171, and the second detection terminal 172, can be increased compared with the case where the plurality of recesses 55 are not provided. Likewise, the creepage distance along the sealing resin 50, between one of the first gate terminal 161 and the second gate terminal 162, and one of the first input terminal 13, output terminal 14, and the second input terminal 15 can be relatively increased. Such a configuration is advantageous in improving the insulation withstand voltage of the semiconductor device A10.

As shown in FIG. 4, FIG. 6, and FIG. 9 to FIG. 11, the groove 56 is recessed from the bottom face 52 in the thickness direction z, and formed in an elongate shape in the second direction y. The groove 56 includes two end portions distant from each other in the second direction y, each of which is connected to one of the pair of second side faces 54. The groove 56 increases the creepage distance along the sealing resin 50, between the first die pad 11 and one of the seven terminals cited above (first input terminal 13, output terminal 14, second input terminal 15, first gate terminal 161, second gate terminal 162, first detection terminal 171, and second detection terminal 172). Likewise, the groove 56 also increases the creepage distance along the sealing resin 50, between the second die pad 12 and one of the seven terminals cited above. Such a configuration is advantageous in improving the insulation withstand voltage of the semiconductor device A10.

The semiconductor device A10 provides the following advantageous effects.

The semiconductor device A10 includes the conductive member (first conductive member 30A) having the main portion 31, the first connecting portion 32, the first joint portion 33, and the distal end portion 34, and the first bonding layer 24 electrically connecting between the conductive member and the electrode (second electrode 212) of the semiconductor element 21 (first switching element 21A). As viewed along the in-plane direction (first direction x in the semiconductor device A10), the distal end portion 34 is inclined so as to be farther from the electrode of the semiconductor element 21, in the direction away from the first connecting portion 32. Further, as viewed along the thickness direction z, the electrode of the semiconductor element 21 includes the expanded region 212A, protruding from the distal end portion 34 to the opposite side of the first connecting portion 32, with respect to the distal end portion 34, in the in-plane direction (second direction y in the semiconductor device A10). Because of the mentioned configuration, the first bonding layer 24 climbs upward along the bent surface 341 of the distal end portion 34, so as to form the fillet 241 having a relatively large volume, as shown in FIG. 15. In a view along the in-plane direction (first direction x in the semiconductor device A10), the inclination angle β1 defined by the fillet 241 with respect to the electrode of the semiconductor element 21 is relatively narrow. The presence of the fillet 241 thus formed enables the thermal stress, concentrating at the interface between the electrode of the semiconductor element 21 and the first bonding layer 24, to be mitigated. Consequently, the semiconductor device A10 can withstanding a larger current, and yet can mitigate the thermal stress imposed on the semiconductor element 21.

In a view along the in-plane direction (first direction x in the semiconductor device A10), the inclination angle β1 defined by the fillet 241, with respect to the electrode of the semiconductor element 21, is narrower than the inclination angle α2 defined by the bent surface 341 of the distal end portion 34, with respect to the first connecting surface 321 of the first connecting portion 32. Such a relation between the inclination angles allows the fillet 241 to have a shape that is advantageous in mitigating the thermal stress concentrating at the interface between the electrode of the semiconductor element 21 and the first bonding layer 24.

As viewed along the in-plane direction (first direction x in the semiconductor device A10), the first joint portion 33 is inclined so as to be farther from the first obverse face 111 of the first die pad 11, in the direction from the first connecting portion 32 toward the main portion 31. As viewed along the thickness direction z, the boundary 332 between the first connecting surface 321 of the first connecting portion 32 and the first inclined surface 331 of the first joint portion 33 is located on the inner side of the peripheral edge of the semiconductor element 21. Accordingly, in the first bonding layer 24, the fillet 241 is formed on both end portions of the electrode of the semiconductor element 21 in the in-plane direction (second direction y in the semiconductor device A10). Therefore, the thermal stress concentrating at the interface between the electrode of the semiconductor element 21 and the first bonding layer 24 can be mitigated more effectively. Specifically, when the inclination angle α1 defined by the first inclined surface 331 with respect to the first connecting surface 321 is between 30° and 60°, both ends inclusive, in a view along the in-plane direction (first direction x in the semiconductor device A10), the fillet 241 is formed in the shape that is advantageous in mitigating the concentration of the thermal stress.

The thickness t of the first connecting portion 32 is equal to or thinner than twice of the maximum thickness Tₘₐₓ of the first bonding layer 24. Such a configuration mitigates the thermal stress, concentrating at the interface between the first bonding layer 24 and the first connecting portion 32, and at the same time secures the thermal endurance of the first bonding layer 24.

The first connecting portion 32 includes the first opening 322 penetrating therethrough in the thickness direction z. Forming thus the first opening 322 allows air bubbles in the first bonding layer 24 in a molten state to be released to outside, when the first connecting portion 32 is electrically connected to the electrode of the semiconductor element 21 via the first bonding layer 24. Further, the first bonding layer 24 is in contact with the inner circumferential surface of the first connecting portion 32 defining the first opening 322. Therefore, the first bonding layer 24 in the molten state attains a self-alignment effect, to locate the first connecting portion 32 at a predetermined position with respect to the electrode of the semiconductor element 21.

The composition of the conductive member contains copper. Therefore, the electrical resistance of the conductive member can be reduced, compared with a wire the composition of which contains aluminum. This is advantageous in supplying a larger current to the semiconductor element 21.

The composition of the first die pad 11 contains copper. In addition, the thickness T1 of the first die pad 11 is thicker than the maximum thickness tₘₐₓ of the conductive member. Such a configuration can both improve the thermal conductivity of the first die pad 11, and improve the thermal conduction efficiency in the in-plane direction. Consequently, the heat dissipation performance of the semiconductor device A10 can be improved.

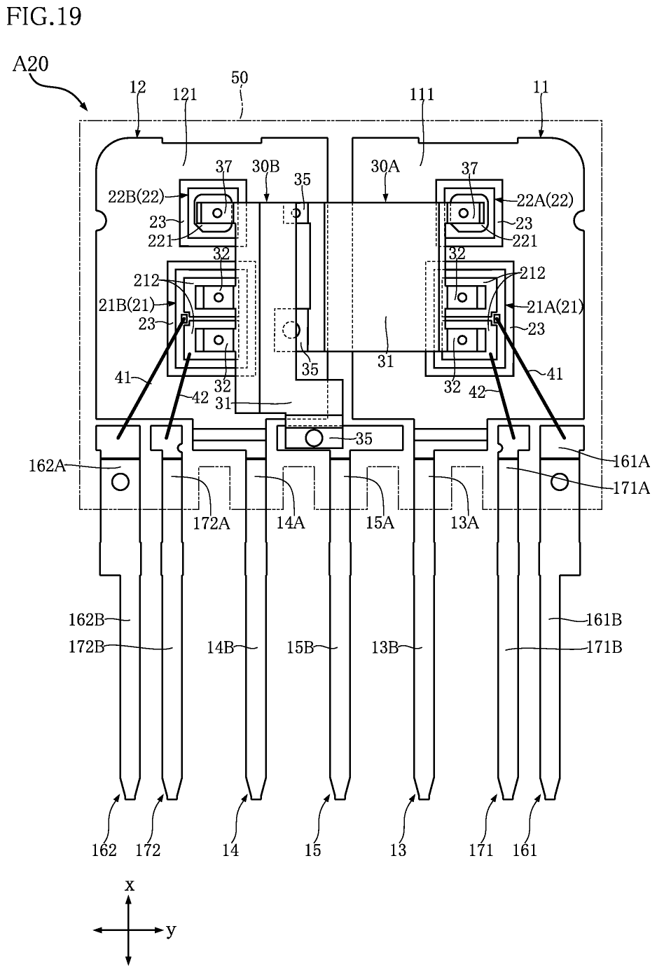

Referring now to FIG. 19 to FIG. 21, a semiconductor device A20 according to a second embodiment of the present disclosure will be described hereunder. In the mentioned drawings, the constituent elements same as or similar to those of the semiconductor device A10 are given the same numeral, and the description of such constituent elements will not be repeated. In FIG. 19, the sealing resin 50 is seen through, for the sake of clarity. In FIG. 19, the sealing resin 50 seen through is indicated by imaginary lines.

The semiconductor device A20 is different from the semiconductor device A10, in the configuration of the second electrode 212 of each of the pair of semiconductor elements 21, and the first connecting portion 32 of each of the first conductive member 30A and the second conductive member 30B.

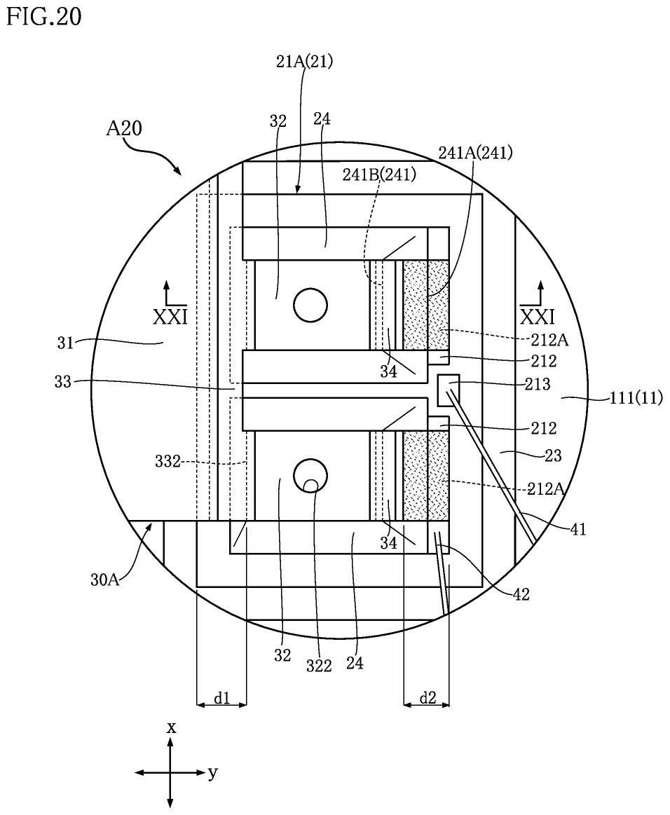

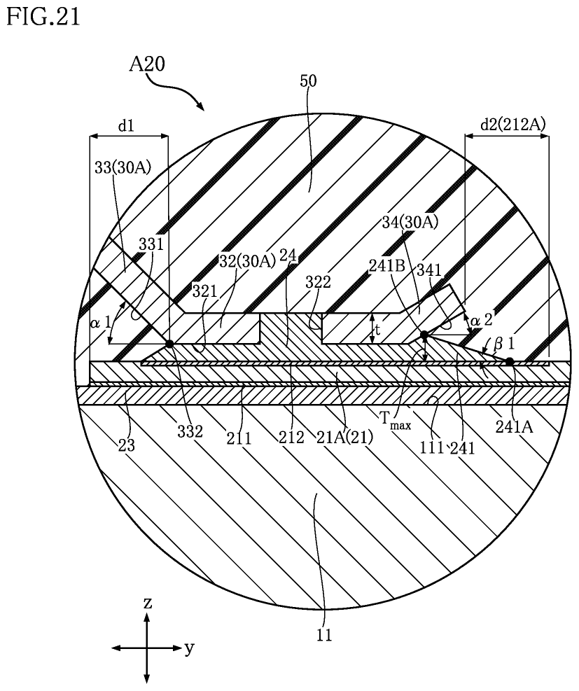

As shown in FIG. 19, the second electrode 212 of each of the semiconductor elements 21 includes a pair of regions spaced apart from each other in the first direction x. The first connecting portion 32 of each of the first conductive member 30A and the second conductive member 30B includes a pair of regions spaced apart from each other in the first direction x. As shown in FIG. 20 and FIG. 21, the pair of regions of the first connecting portion 32 of the first conductive member 30A are respectively and electrically connected to the pair of regions of the second electrode 212 of the first switching element 21A, via the first bonding layer 24. Likewise, the pair of regions of the first connecting portion 32 of the second conductive member 30B are respectively and electrically connected to the pair of regions of the second electrode 212 of the second switching element 21B, via the first bonding layer 24.

The semiconductor device A20 provides the following advantageous effects.

The semiconductor device A20 includes the conductive member (first conductive member 30A) having the main portion 31, the first connecting portion 32, the first joint portion 33, and the distal end portion 34, and the first bonding layer 24 electrically connecting between the conductive member and the electrode (second electrode 212) of the semiconductor element 21 (first switching element 21A). As viewed along the in-plane direction (first direction x in the semiconductor device A10), the distal end portion 34 is inclined so as to be farther from the electrode of the semiconductor element 21, in the direction away from the first connecting portion 32. Further, as viewed along the thickness direction z, the electrode of the semiconductor element 21 includes the expanded region 212A, protruding from the distal end portion 34 to the opposite side of the first connecting portion 32, with respect to the distal end portion 34, in the in-plane direction (second direction y in the semiconductor device A10). Therefore, the semiconductor device A20 can also withstand a larger current, and yet can mitigate the thermal stress imposed on the semiconductor element 21. Further, the semiconductor device A20 also provides various other advantageous effects provided by the semiconductor device A10.

The present disclosure is not limited to the foregoing embodiments. The specific configuration of each of the elements in the present disclosure may be modified in various manners.

The semiconductor device, and the manufacturing method thereof according to the present disclosure may be defined as the following Clauses.

### Clause 1.

A semiconductor device including:
a first die pad having a first obverse face facing in a thickness direction;
a semiconductor element having an electrode located on a side to which the first obverse face is oriented in the thickness direction, the semiconductor element being connected to the first obverse face;
a conductive member electrically connected to the electrode; and
a first bonding layer electrically connecting the conductive member and the electrode,
in which the conductive member includes a main portion, a first connecting portion electrically connected to the electrode via the first bonding layer, a first joint portion connecting the main portion and the first connecting portion, and a distal end portion spaced apart from the first joint portion, and connected to the first connecting portion,
as viewed along an in-plane direction of the first obverse face, the distal end portion is inclined so as to be farther from the electrode, in a direction away from the first connecting portion, and
as viewed along the thickness direction, the electrode includes an expanded region, protruding from the conductive member to an opposite side of the first connecting portion in the in-plane direction, with respect to the distal end portion.

### Clause 2.

The semiconductor device according to Clause 1, in which the first die pad and the conductive member each contain copper.

### Clause 3.

The semiconductor device according to Clause 1 or 2, in which the first bonding layer contains tin.

### Clause 4.

The semiconductor device according to Clause 3, in which, as viewed along the in-plane direction, the first bonding layer includes a fillet formed on the electrode so as to reach the conductive member, and inclined with respect to the electrode,

the fillet includes a first edge in contact with the electrode, and a second edge in contact with the conductive member, and

the first edge is located on an outer side from the second edge, as viewed along the thickness direction.

### Clause 5.

The semiconductor device according to Clause 4, in which the first connecting portion includes a connecting surface opposed to the electrode, and located in contact with the first bonding layer,

the distal end portion includes a bent surface connected to the connecting surface, and inclined with respect to the connecting surface, and

as viewed in the in-plane direction, an inclination angle defined by the fillet with respect to the electrode is narrower than an inclination angle defined by the bent surface with respect to the connecting surface.

### Clause 6.

The semiconductor device according to Clause 5, in which the second edge is in contact with the bent surface.

### Clause 7.

The semiconductor device according to Clause 5 or 6, in which, as viewed along the in-plane direction, the first joint portion is inclined so as to be farther from the first obverse face, in a direction from the first connecting portion toward the main portion.

### Clause 8.

The semiconductor device according to Clause 7, in which the first joint portion includes an inclined surface connected to the connecting surface and inclined with respect to the connecting surface, and

as viewed along the thickness direction, a boundary between the connecting surface and the inclined surface is located on an inner side of a peripheral edge of the semiconductor element.

### Clause 9.

The semiconductor device according to Clause 8, in which, as viewed along the in-plane direction, an inclination angle defined by the inclined surface with respect to the connecting surface is between 30° and 60°, both ends inclusive.

### Clause 10.

The semiconductor device according to any one of Clauses 3 to 9, in which a thickness of the first connecting portion is equal to or thinner than twice of a maximum thickness of the first bonding layer.

### Clause 11.

The semiconductor device according to any one of Clauses 3 to 10, in which the first connecting portion includes an opening penetrating in the thickness direction, and

the first bonding layer is in contact with an inner circumferential surface of the first connecting portion defining the opening.

### Clause 12.

The semiconductor device according to any one of Clauses 1 to 11, in which a thickness of the first die pad is thicker than a maximum thickness of the conductive member.

### Clause 13.

The semiconductor device according to any one of Clauses 1 to 12, further including:

a second die pad including a second obverse face oriented in a same direction as the first obverse face in the thickness direction, and spaced apart from the first die pad in the in-plane direction; and

a second bonding layer electrically connecting the conductive member and the second obverse face,

in which the conductive member includes a second connecting portion electrically connected to the second obverse face via the second bonding layer, and a second joint portion connecting between the main portion and the second connecting portion,

the second die pad contains copper, and

the second bonding layer contains tin.

### Clause 14.

The semiconductor device according to Clause 13, in which, as viewed along the in-plane direction, the second joint portion is inclined so as to be farther from the second obverse face, in a direction from the second connecting portion toward the main portion.

### Clause 15.

The semiconductor device according to Clause 13 or 14, in which a thickness of the second die pad is thicker than a maximum thickness of the conductive member.

### Clause 16.

The semiconductor device according to any one of Clauses 13 to 15, further including a sealing resin covering a part of each of the first die pad and the second die pad, the semiconductor element, and the conductive member,

in which the first die pad includes a first reverse face, oriented to an opposite side of the first obverse face in the thickness direction,

the second die pad includes a second reverse face, oriented to an opposite side of the second obverse face in the thickness direction, and

the first reverse face and the second reverse face are exposed from the sealing resin.

### Clause 17.

The semiconductor device according to any one of Clauses 1 to 16, in which the semiconductor element includes a chemical compound semiconductor substrate.

### Clause 18.

The semiconductor device according to Clause 17, in which the chemical compound semiconductor substrate contains silicon carbide.

### REFERENCE SIGNS

| | |
|---|---|
| A10, A20: semiconductor device | 11: first die pad |
| 111: first obverse face | 112: first reverse face |
| 12: second die pad | 121: second obverse face |
| 122: second reverse face | 13: first input terminal |
| 13A: covered portion | 13B: exposed portion |
| 14: output terminal | 14A: covered portion |
| 14B: exposed portion | 15: second input terminal |
| 15A: covered portion | 15B: exposed portion |
| 161: first gate terminal | 161A: covered portion |
| 161B: exposed portion | 162: second gate terminal |
| 162A: covered portion | 162B: exposed portion |
| 171: first detection terminal | 171A: covered portion |
| 171B: exposed portion | 172: second detection terminal |
| 172A: covered portion | 172B: exposed portion |
| 21: semiconductor element | 21A: first switching element |
| 21B: second switching element | 211: first electrode |
| 212: second electrode | 212A: expanded region |
| 213: third electrode | 22: protection element |
| 22A: first diode | 22B: second diode |
| 221: upper electrode | 221A: expanded region |
| 222: lower electrode | 23: die bonding layer |
| 24: first bonding layer | 241: fillet |
| 241A: first edge | 241B: second edge |
| 25: second bonding layer | 26: third bonding layer |
| 261: fillet261A: first edge | 261B: second edge |
| 30A: first conductive member | 30B: second conductive member |
| 31: main portion | 32: first connecting portion |
| 321: first connecting surface | 322: first opening |
| 33: first joint portion | 331: first inclined surface |
| 332: boundary | 34: distal end portion |
| 341: bent surface | 35: second connecting portion |
| 351: second connecting surface | 352: second opening |
| 36: second joint portion | 361: second inclined surface |
| 37: third connecting portion | 371: third connecting surface |
| 372: third opening | 38: distal end portion |
| 381: bent surface | 41: gate wire |

42: detection wire 50: sealing resin
51: top face 52: bottom face
53: first side face 54: second side face
55: recess 56: groove
z: thickness direction x: first direction
y: second direction

1. A semiconductor device comprising:
a first die pad including a first obverse face facing in a thickness direction;
a semiconductor element including an electrode located on a side to which the first obverse face faces in the thickness direction, the semiconductor element being connected to the first obverse face;
a conductive member electrically connected to the electrode; and
a first bonding layer electrically connecting the conductive member and the electrode,
wherein the conductive member includes a main portion, a first connecting portion electrically connected to the electrode via the first bonding layer, a first joint portion connecting the main portion and the first connecting portion, and a distal end portion spaced apart from the first joint portion, and connected to the first connecting portion,
as viewed along an in-plane direction of the first obverse face, the distal end portion is inclined so as to be farther from the electrode in a direction away from the first connecting portion, and
as viewed along the thickness direction, the electrode includes an expanded region, protruding from the conductive member to an opposite side of the first connecting portion in the in-plane direction, with respect to the distal end portion.

2. The semiconductor device according to claim 1, wherein the first die pad and the conductive member each contain copper.

3. The semiconductor device according to claim 1, wherein the first bonding layer contains tin.

4. The semiconductor device according to claim 3, wherein, as viewed along the in-plane direction, the first bonding layer includes a fillet formed on the electrode so as to reach the conductive member, and inclined with respect to the electrode,
the fillet includes a first edge in contact with the electrode, and a second edge in contact with the conductive member, and
the first edge is located on an outer side from the second edge, as viewed along the thickness direction.

5. The semiconductor device according to claim 4, wherein the first connecting portion includes a connecting surface opposed to the electrode, and located in contact with the first bonding layer,
the distal end portion includes a bent surface connected to the connecting surface, and inclined with respect to the connecting surface, and
as viewed in the in-plane direction, an inclination angle defined by the fillet with respect to the electrode is narrower than an inclination angle defined by the bent surface with respect to the connecting surface.

6. The semiconductor device according to claim 5, wherein the second edge is in contact with the bent surface.

7. The semiconductor device according to claim 5, wherein, as viewed along the in-plane direction, the first joint portion is inclined so as to be farther from the first obverse face, in a direction from the first connecting portion toward the main portion.

8. The semiconductor device according to claim 7, wherein the first joint portion includes an inclined surface connected to the connecting surface and inclined with respect to the connecting surface, and
as viewed along the thickness direction, a boundary between the connecting surface and the inclined surface is located on an inner side of a peripheral edge of the semiconductor element.

9. The semiconductor device according to claim 8, wherein, as viewed along the in-plane direction, an inclination angle defined by the inclined surface with respect to the connecting surface is between 30° and 60°, both ends inclusive.

10. The semiconductor device according to claim 3, wherein a thickness of the first connecting portion is equal to or thinner than twice of a maximum thickness of the first bonding layer.

11. The semiconductor device according to claim 1, wherein a thickness of the first die pad is thicker than a maximum thickness of the conductive member.

12. The semiconductor device according to claim 1, further comprising:
a second die pad including a second obverse face oriented in a same direction as the first obverse face in the thickness direction, and spaced apart from the first die pad in the in-plane direction; and
a second bonding layer electrically connecting the conductive member and the second obverse face,
wherein the conductive member includes a second connecting portion electrically connected to the second obverse face via the second bonding layer, and a second joint portion connecting between the main portion and the second connecting portion,
the second die pad contains copper, and
the second bonding layer contains tin.

13. The semiconductor device according to claim 12, wherein, as viewed along the in-plane direction, the second joint portion is inclined so as to be farther from the second obverse face, in a direction from the second connecting portion toward the main portion.

14. The semiconductor device according to claim 12, wherein a thickness of the second die pad is thicker than a maximum thickness of the conductive member.

15. The semiconductor device according to claim 12, further comprising a sealing resin covering a part of each of the first die pad and the second die pad, the semiconductor element, and the conductive member,
wherein the first die pad includes a first reverse face, oriented to an opposite side of the first obverse face in the thickness direction,
the second die pad includes a second reverse face, oriented to an opposite side of the second obverse face in the thickness direction, and
the first reverse face and the second reverse face are exposed from the sealing resin.
